(19) United States
(12) Patent Application Publication
(10) Pub. No.: US 2019/0200450 A1
(43) Pub. Date: Jun. 27, 2019

(54) ALTERNATIVE CIRCUIT APPARATUS FOR LONG HOST ROUTING

(71) Applicant: Intel Corporation, Santa Clara, CA (US)

(72) Inventors: Richard I. MELLITZ, Prosperity, SC (US); Brandon GORE, West Columbia, SC (US); Beom-Taek LEE, Mountain View, CA (US)

(73) Assignee: Intel Corporation, Santa Clara, CA (US)

(21) Appl. No.: 16/328,412

(22) PCT Filed: Sep. 19, 2017
(86) PCT No.: PCT/US2017/052210

§ 371 Date: Feb. 26, 2019

Related U.S. Application Data
(60) Provisional application No. 62/396,329, filed on Sep. 19, 2016.

(51) Int. Cl. H05K 1/02; H05K 1/18; H05K 1/11; H05K 1/14; H01R 12/71

(52) U.S. Cl. CPC H05K 1/0243; H05K 1/181; H05K 1/112; H05K 1/144; H05K 1/028; H05K 2201/042; H05K 2201/10378; H05K 2201/10734; H05K 2201/10189; H05K 2201/10356; H01R 12/716

(57) ABSTRACT

Methods and apparatus for utilizing flexible (flex) circuit technology and/or axial cable to facilitate routing of high-speed data channels are described herein. Under one aspect, a high-speed data channel if routed between an integrated circuit (IC) and a high-speed data connector mounted to a multilayer printed circuit board as part of a circuit assembly. The circuit assembly includes a signal pathway providing a high-speed data channel from the integrated circuit to the high-speed data connector, wherein a portion of the signal pathway includes a flex circuit or axial cable.

### BACKGROUND INFORMATION

High speed communication for networking and other communication infrastructure is constantly improving for facilitation of cloud computing, cloud storage, video conferencing, streaming and other applications. Transfer rates for today's infrastructure is commonly measured in Gigabits per second (Gb/s), for example. In order to meet these high bandwidth capabilities, the Physical (PHY) layer must be designed to facilitate the data exchange through the routing pathways.

Despite the advances in transfer rates, the ecosystems for networking and storage remain cost-sensitive, which limits the material and design choices of components for high-speed networking and storage systems. In particular, printed circuit boards (PCBs) are used extensively in networking and storage systems to route signals and data to the proper circuitry. However, the market will not tolerate increasing the PCB cost and/or complexities even as the requirements for high-speed data transfer increases.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 illustrates an embodiment of a baseline reach of 10 inches from an integrated circuit (IC) to a connector;

FIG. 2 illustrates an embodiment of a ball grid array (BGA) flex circuit carrying a high-speed data channel, in accordance with an embodiment of the disclosure.

FIG. 3 is a graph illustrating approximately 50% less signal attenuation of high cost, optimized PCB construction compared to low cost server PCB;

FIG. 4 is a graph illustrating approximately 50% better signal attenuation for a 10 inch host reach using flex circuit technology according to one embodiment versus a 10 inch host reach on low cost non-optimized PCB;

FIG. 5 is a graph that demonstrates meeting part of IEEE Std. 802.3 Clause 110 (25 GBASE-CR) transmitter specification with one embodiment of a flex circuit apparatus;

FIG. 6 is a graph showing that a baseline apparatus does not meet the IEEE Std. 802.3 Clause 110 (25 GBASE-CR) transmitter specification for 10 inch reach on low cost PCB with non-optimized layer construction;

FIG. 7 illustrates an example circuit assembly having a top board flex circuit;

FIG. 8 illustrates an example circuit assembly having a packet to board flex circuit;

FIG. 9 illustrates an example circuit assembly having a top flexible twin axial attachment;

FIG. 10 illustrates an example circuit assembly having a top package flexible twin axial assembly; and

FIG. 11 illustrates an example circuit assembly having a bottom flexible twin axial attachment.

### DETAILED DESCRIPTION

Embodiments of methods and apparatus for utilizing flexible (flex) circuit technology and/or axial cable to facilitate routing of high-speed data channels are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

As discussed above, PCBs are used in networking and storage components. PCBs are subject to cost constraints while also being required to meet high-speed data requirements. High-speed Ethernet protocols are examples of networking protocols with high-speed data requirement. Some Integrated Circuits (IC) have integrated Ethernet that is designed to comply with IEEE 802.3 standards to achieve 10 Gb/s, 25 Gb/s, and 50 Gb/s per lane over copper Ethernet, for example. Multi-lane Ethernet standards have also been defined, including IEEE 802.3bj-2014 100 Gb/s Ethernet that employs four 25 Gb/s lanes operated in parallel. Host PCBs (that host the ICs) can have relatively long distances (e.g., greater than 3 inches) from where the IC is positioned to where a data connector (e.g. Ethernet connector) is located. Example ICs includes central processing units (CPUs), system-on-chip (SoC) chips, including processors with SoC architectures, and Platform Controller Hubs (PCH).

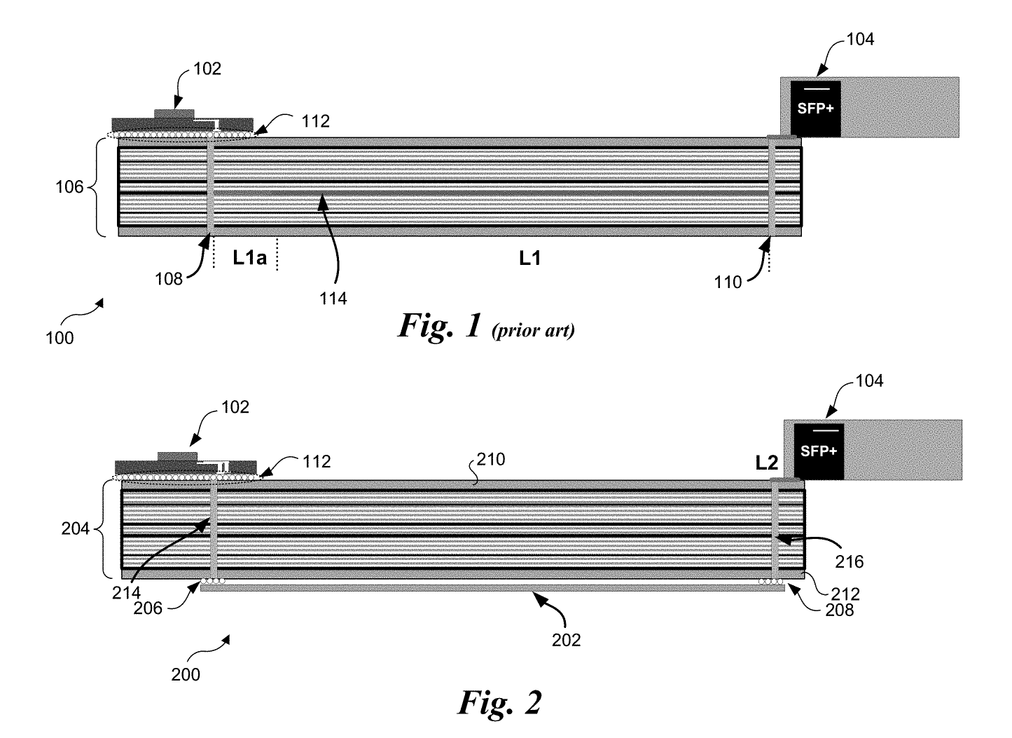

FIG. 1 illustrates one embodiment of a circuit assembly 100 having a baseline reach of 10 inches from an integrated circuit (IC) 102 to a connector 104. In FIG. 1, connector 104 is a small form-factor pluggable (SFP) connector. Circuit assembly 100 includes a multilayer PCB 106 having a plurality of vias 108 and 110 formed therein. A high-speed data channel is routed from IC 102 through ball grid array (BGA) 112 to vias 108. A routing layer 114 formed as an inner layer in multilayer PCB connects vias 108 to vias 110 and the high-speed data channel is routed from routing layer 114 to via 110, and on to connector 104. Therefore, the high-speed data channel (e.g., Ethernet) is routed from IC 102 to connector 104 through a layer of multilayer PCB 106. As further depicted, the layer includes two section: and L1a section and an L1 section. In addition to the illustrated SFP connectors herein, connector 104 may be configured to receive other types of cables, such as Ethernet cables using jacks other than SFP jacks.

As depicted in various drawing figures herein, the use of one or more BGAs are used. A ball grid array is a type of packaging under which an array of pads arranged in a grid (the grid array) on the underside of an integrated circuit (commonly referred to as an IC or chip) are electrically coupled to a similar array of pads having the same grid configuration and patterned on an outer layer on a PCB, wherein respective pairs of pads on the IC and PCB are coupled via a solder ball. During a manufacturing process, the solder balls are melted (e.g., via a reflow operation), resulting in the respective pairs of pads being electrically coupled, enabling signals to pass from the IC to “wiring” on one or more PCB layers connected to the array of pads patterned on the surface of the PCB. For example, in the example of FIG. 1 and embodiments illustrated in FIGS. 2, 7-11, selected pads for the grid array patterned on the PCB surface are coupled to vias formed in the PCB, such as vias 108 in FIG. 1. It will be understood by those skilled in the art that only a portion of the pads patterned on the PCB are connected to the vias illustrated herein, or otherwise connected to wiring formed in the same layer on the PCB as the patterned BGA pads or intermediate substrate (such as shown in FIG. 8). Further details of BGA packages and the interconnections between BGA pads and vias are discussed below with reference to FIGS. 12 and 13.

It will also be recognized by those of skill in the art that the terms “wiring,” “traces,” and “wiring traces” are commonly referred to electric pathways patterns formed on a layer in a PCB. For example, such electric pathways are generally patterned on a PCB by etching a copper layer or through a similar manufacturing process that selectively removes portions of the copper layer, leaving a pattern of “wiring” or “traces” that is used to interconnect components mounted to the PCB.

Pads and/or traces on different layers in a multilayer PCB may be electrically coupled using vias. A via is generally formed by drilling or punching a small hole in the PCB or otherwise forming a similar hole using a manufacturing process. During subsequent processes, a conductive material is formed on the surface of the hole forming a conductive tube or “barrel,” such as via a plating processes. As such, a via that passes completely through a PCB is commonly referred to as a “plated-through hole”, “plated-through hole via,” or through-hole via. In addition to through-hole vias, blind vias and buried vias may also be used. A blind via is similar to a through-hole via, except that the hole only passes through one surface of the PCB. A buried via has a hole that is internal to a PCB that doesn't pass through either of the surfaces of the PCB. For simplicity, the terms “via” and “vias” are used in the following description to encompass these various types of vias.

FIG. 2 illustrates a circuit assembly 200 having a BGA flex circuit 202 carrying a high-speed data channel, in accordance with an embodiment of the disclosure. Circuit assembly 200 includes an IC 102, a connector 104, and a multilayer PCB 204. IC 102 is coupled to a top layer of multilayer PCB 204 via a BGA 112. BGA flex circuit 202 includes a pair of BGA connectors 206 and 208 at its opposing ends. IC 102 and BGA 112 may be integrated into a single BGA package, such as a ceramic ball grid array (CBGA), as illustrated in FIG. 12 and described below.

BGA 112 and BGA connectors 206 and 208 are respectively coupled to BGA pad arrays patterned on the outer layers of multilayer PCB 204, which include a top layer 210 and a bottom layer 212. Selective BGA pads patterned on top layer 210 and used for BGA 112 are electrically coupled to BGA pads patterned on bottom layer 212 for BGA connector 206 using a plurality of vias 214. Meanwhile, BGA pads patterned on bottom layer 212 for BGA connector 208 are electrically coupled to wiring in a routing layer L2 formed on the surface of top layer 210 using a plurality of vias 216. Wiring in routing layer L2 is connected to pins on connector 104.

Under a circuit assembly 200, the high-speed data channel is routed from IC 102 through BGA 112, vias 215, BGA 206, flex circuit 202, BGA 208, vias 216, routing layer L2, to high-speed data connector 104.

In one embodiment, IC 102 has an integrated high-speed data transceiver (e.g. Ethernet) for sending and receiving data. Other examples of high-speed data interfaces that may make use of this disclosure include UltraPath Interconnect (UPI), Peripheral Component Interconnect Express (PCIe), Serial AT Attachment (SATA), Serial Attached SCSI (SAS), Universal Serial Bus (USB), Fiber Channel, InfiniBand, and memory. Single ended busses such as double data rate (DDR) busses may use the embodiments of the disclosure.

Generally, the high-speed data may be 1 Gb/s or greater. In some embodiments, the high-speed data channel has a bandwidth of 25 Gb/s, while in other embodiments the bandwidth may be 50 Gb/s or greater per lane and 100 Gb/s or greater for a multi-lane link. The high-speed data channel in FIG. 2 is routed from IC 102, through BGA 112, vias 214, BGA flex circuit 202, vias 216, and then to connector 104 via wiring in routing layer L2.

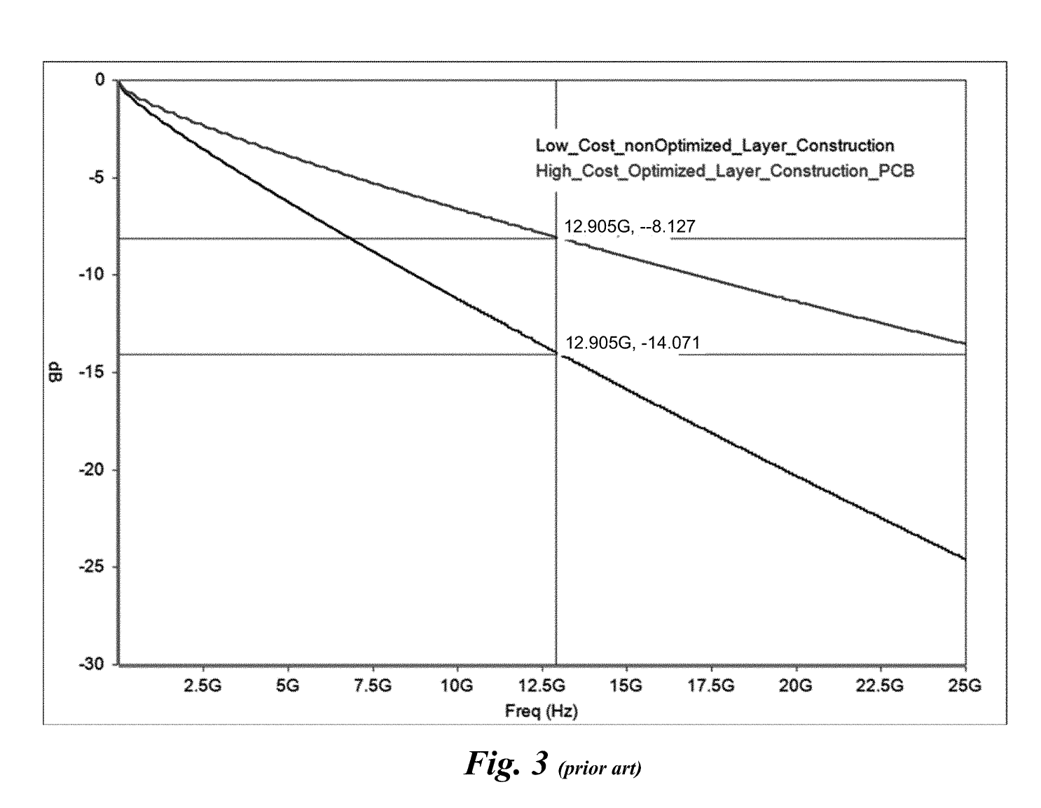

FIG. 3 is a signal attenuation (dB) versus Frequency graph for 8 inches of high cost, optimized layer construction (e.g. fabric switch routing) and 8 inches of low cost, non-optimized layer construction (e.g. server routing). As shown, the high-cost, optimized PCB construction provides approximately 50% less signal attenuation compared to a low cost server PCB. Although the high cost optimized PCB reduces attenuation, it is significantly more expensive than the low cost PCB construction.

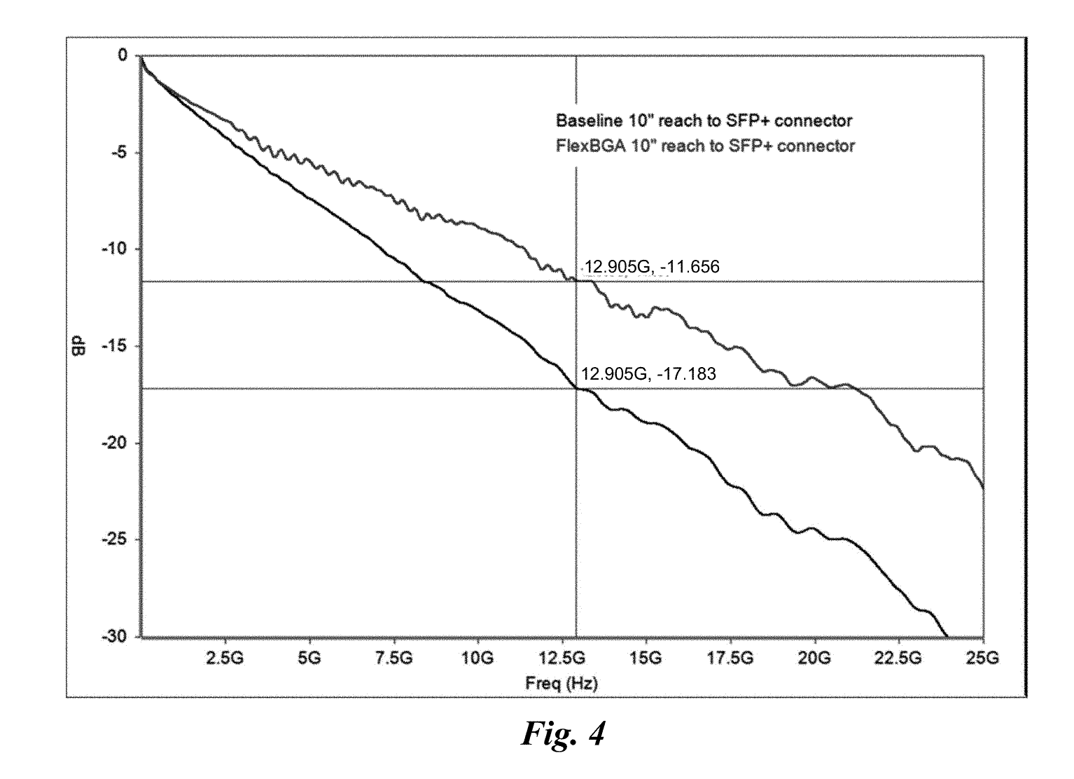

FIG. 4 is a signal attenuation (dB) versus Frequency graph that illustrates approximately 50% better signal attenuation for a 10 inch host reach using one embodiment of flex circuit technology versus a 10 inch host reach on low cost non-optimized PCB. As this demonstrates, flex circuit technology yields similar results to high cost optimized PCBs. However, the flex circuit technology is less expensive than high cost optimized PCBs for similar applications.

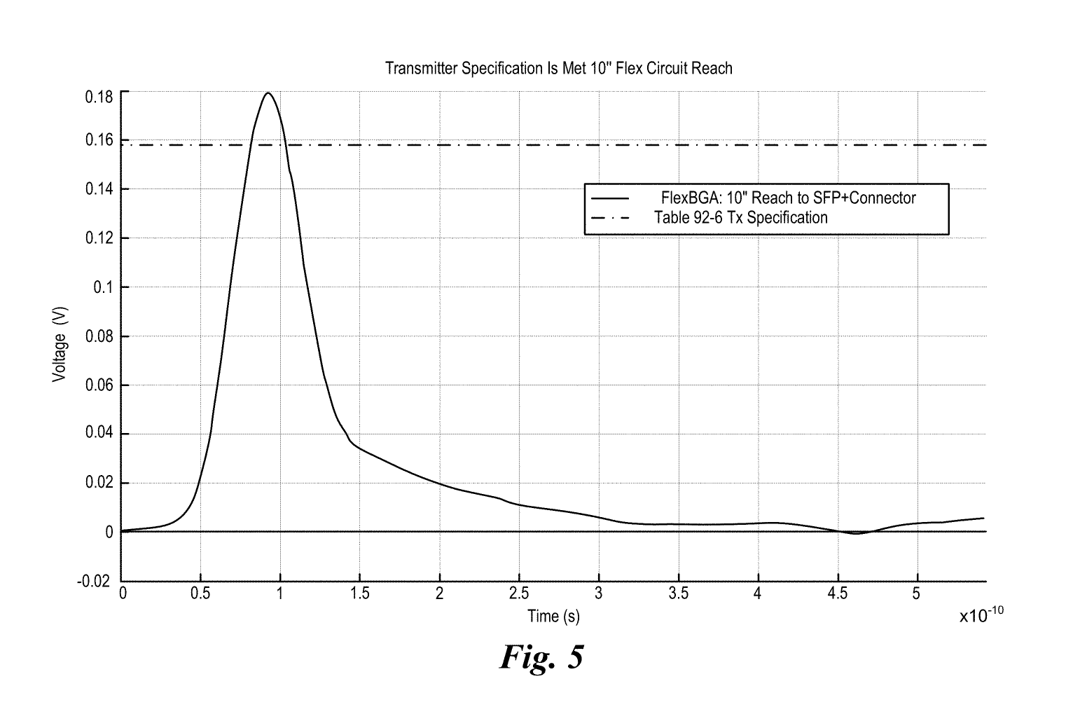

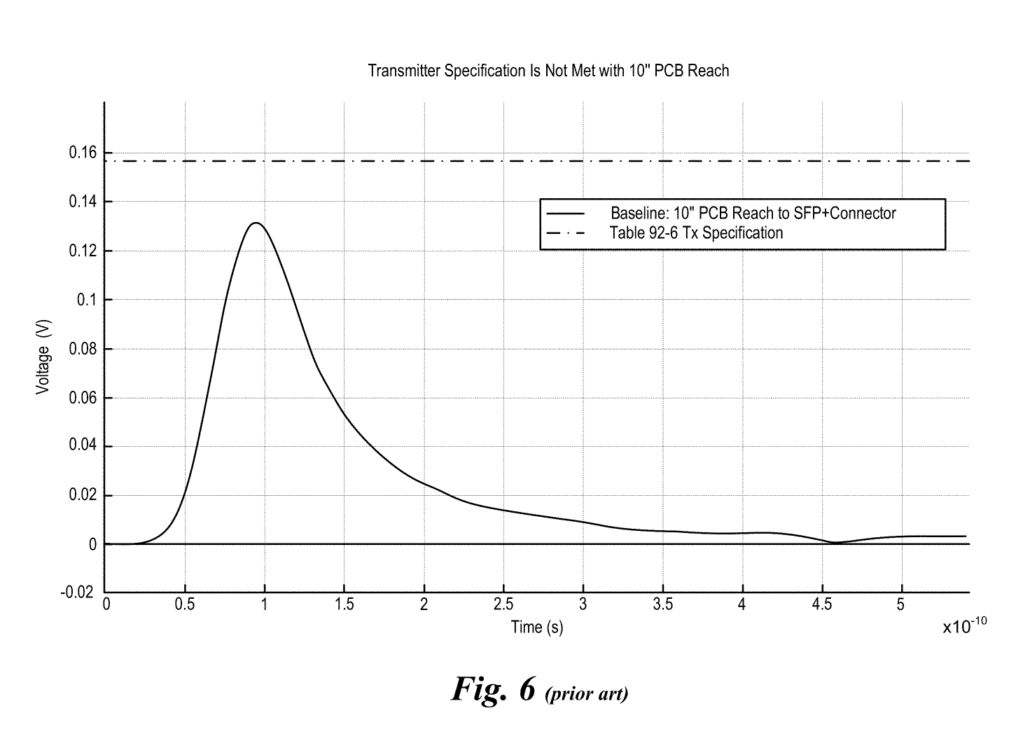

FIG. 5 is a graph that demonstrates meeting part of IEEE Std. 802.3 Clause 110 (25 GBASE-CR) transmitter specification with one embodiment of a flex circuit apparatus. In this example, a flex circuit apparatus having a 10 inch reach to an SFP+ connector meets the Table 92-6 Transmit Specification defined in Table 92-6 of IEEE Std 802.3-2012. Conversely, FIG. 6 shows that a conventional baseline configuration having a 10 inch reach on low cost PCB with non-optimized layer construction does not meet the Transmit Specification defined in in Table 92-6 of IEEE Std 802.3-2012.

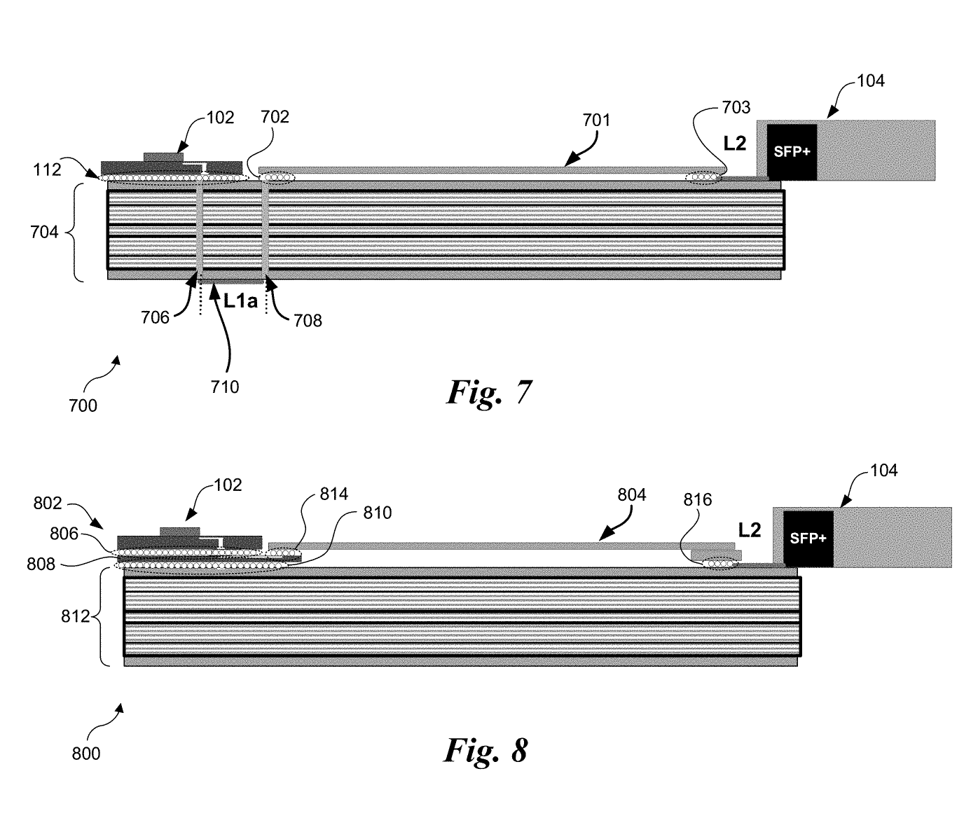

FIG. 7 illustrates an example circuit assembly 700 having a top board BGA flex circuit 701 including BGA connections 702 and 703, in accordance with one embodiment. Circuit assembly 700 further includes an IC 102 coupled to a BGA 112, a connector 104, and a multilayer PCB 704 having vias 706 and 708 formed therein. A high-speed data channel is routed from IC 102 through BGA 112, to selected BGA pads patterned on a top layer of multilayer PCB 704 to vias 706, through wiring in a routing layer 710 (layer L1A), vias 708, BGA connection 702, top board BGA flex circuit 701, BGA connection 702, and wiring in routing layer L2 to connector 104. Vias 706 and 708 are coupled together by signal pathways in layer L1A, which may be a copper layer of PCB 704 in one embodiment. Layer L2 may also be a copper layer of PCB 704.

FIG. 8 illustrates an example circuit assembly 800 including a package comprising multi-level BGA/chip carrier 802 and a package to board flex circuit 804, in accordance with an embodiment of the disclosure. BGA/chip carrier 802 includes an IC 102 including a first BGA 806 mounted to the chip carrier/interposer board 808 comprising a PCB or substrate that is interposed between first BGA 806 and a second BGA 810 mounted to a multilayer PCB 812 via a first set of BGA pads patterned on an upper layer of a multilayer PCB 812. The left end of flex circuit 804 is mounted to the topside of chip carrier 808 by means of a BGA 814, while the right end of flex circuit 804 is mounted to multilayer PCB 812 via a second set of BGA pads patterns on the upper layer of the PCB. The second set of pads are electrically connected to connector 104 via wiring in a layer L2.

Under circuit assembly 800, a high-speed data channel is routed from IC 102 through first BGA 806, chip carrier/interposer board 808, BGA 814, flex circuit 804, BGA 816, and wiring in routing layer L2 of multilayer PCB 812 to connector 104.

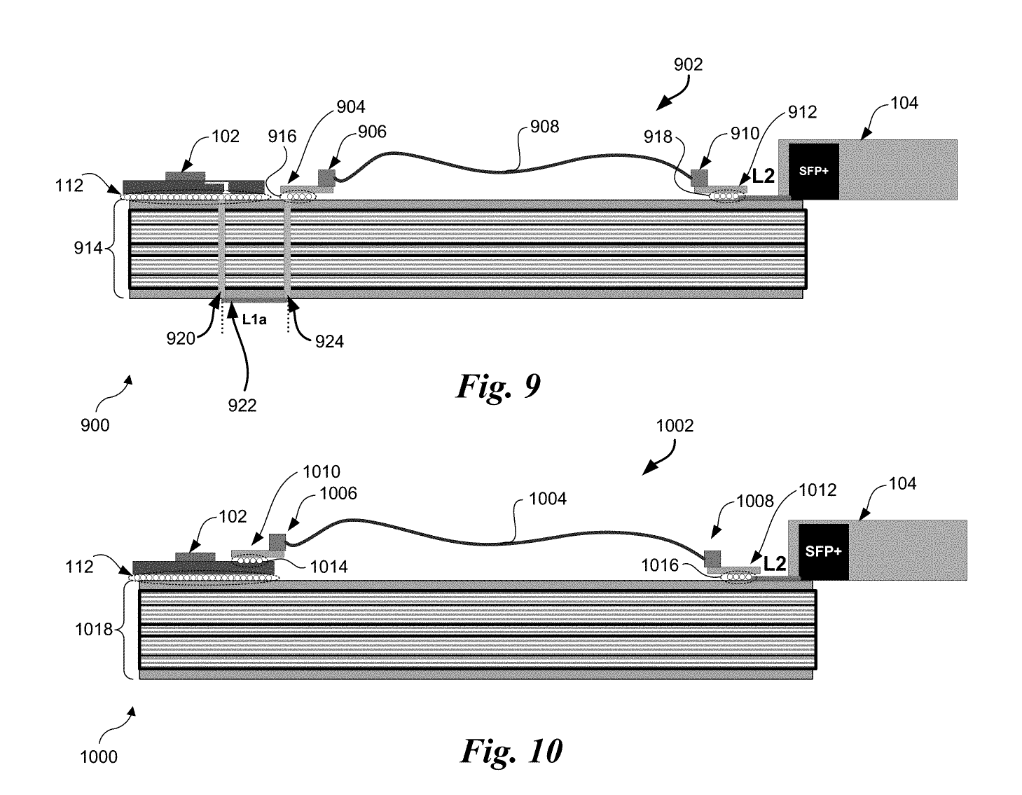

FIG. 9 illustrates an example circuit assembly 900 having a top flexible twin axial attachment 902, in accordance with an embodiment of the disclosure. Top flexible twin axial attachment 902 includes a flex circuit 904, an axial port 906, a twin axial cable 908, an axial port 910, and a flex circuit 912. Axial ports 906 and 910 may be connectors that connect with mating connectors of twin axial cable 908. In the illustrated embodiment, flex circuit 904 is coupled to a multilayer PCB 914 via a ball grid array 916 and axial port 906 is coupled to flex circuit 904. Similarly, flex circuit 912 is coupled to multilayer PCB 914 via a ball grid array 918 and axial port 910 is coupled to flex circuit 912.

In circuit assembly 900, a high-speed data channel is routed from an IC 102 through BGA 112 to vias 920 in multilayer PCB 914, a routing layer 922 (layer L1a of PCB 914), vias 924, BGA 916, flexible twin axial attachment 902, BGA 918, and a layer L2 of PCB 914 to a connector 104.

FIG. 10 illustrates an example circuit assembly 1000 having a top package flexible twin axial assembly 1002, in accordance with an embodiment of the disclosure. Top package flexible twin axial assembly 1002 includes a twin axial cable 1004 coupled between a pair of axial ports 1006 and 1008, which are respectively mounted to flex circuits 1010 and 1012. Top package flexible twin axial assembly 1002 is coupled at its left end to the top of the chip carrier portion of BGA 112 by way of a ball grid array 1014 of flex circuit 1010. Meanwhile, top package flexible twin axial assembly 1002 is coupled at its right end via a ball grid array 1016 that includes pads patterned on a multilayer PCB 1018 connected to a Layer L2 of the PCB.

In circuit assembly 1000, the high-speed data channel is routed from IC 102 through the substrate of BGA 112, to BGA 1014, flex circuit 1010, axial port 1006, twin axial cable 1004, axial port 1008, flex circuit 1012, BGA 1016, layer L2 of PCB 1020, and then to connector 104.

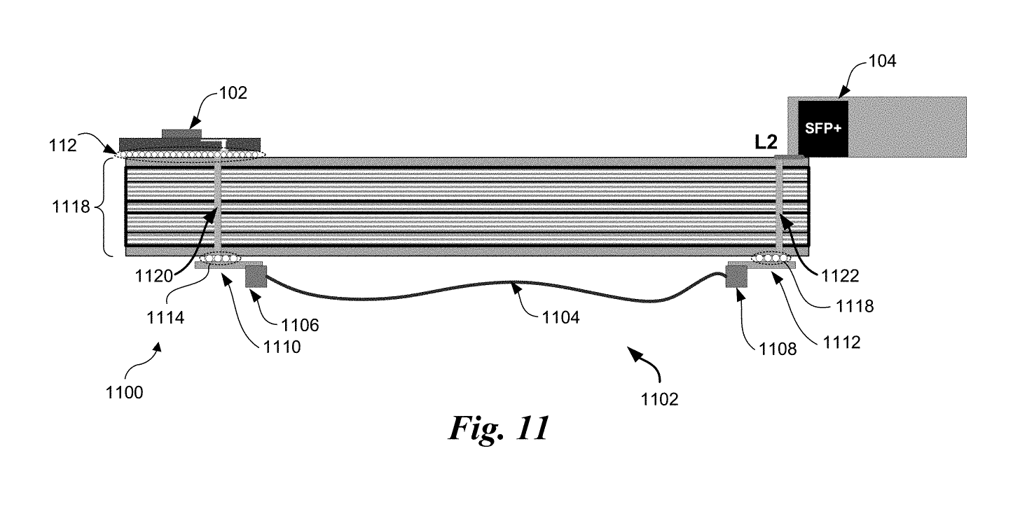

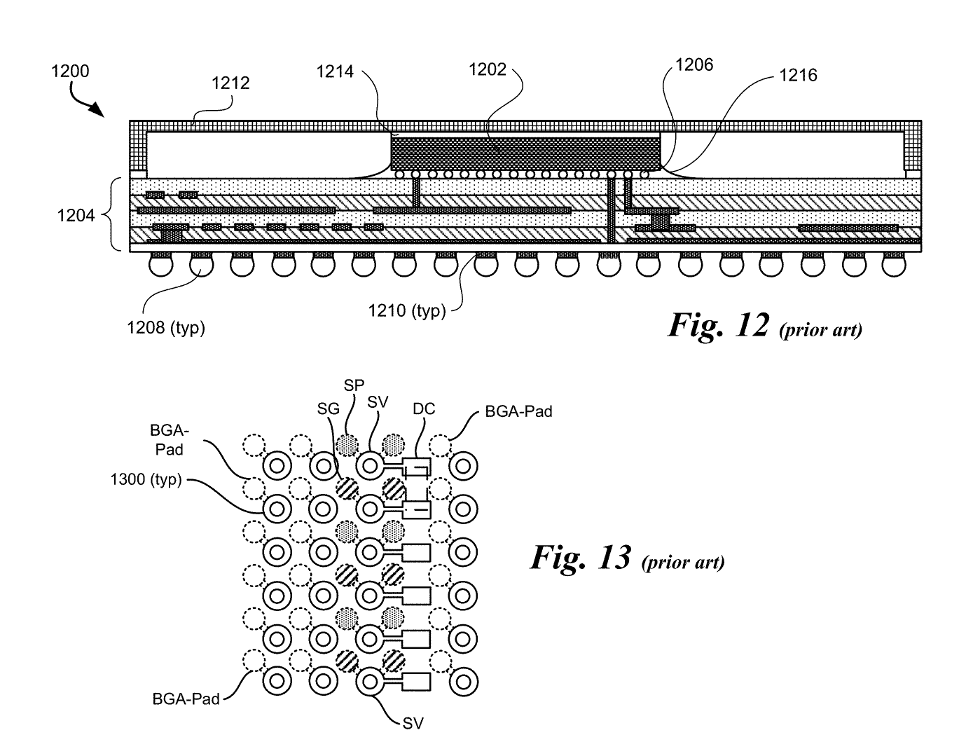

FIG. 11 illustrates an example circuit assembly 1100 having a bottom flexible twin axial attachment 1102, in accordance with an embodiment of the disclosure. Flexible twin axial attachment 1102 includes a twin axial cable 1104 coupled between a pair of an axial ports 1106 and 1108, which in turn are mounted to flex circuits 1110 and 1112. Flex circuit 1110 is mounted by means of a BGA 1114 to the bottom layer of a multilayer PCB 1118, through which vias 1120 and 1122 are formed. As before, IC 102 is mounted to a top layer of multilayer PCB 1118 using a ball grid array 112. Meanwhile, at the opposing end of flexible twin axial attachment 1102, flex circuit 1112 is mounted to the bottom layer of multilayer PCB 1118 by means of BGA 1124, which are electrically connected to vias 1122, which in turn are electrically connected to layer L2 to which connector 104 is coupled.

In circuit assembly 1100, the high-speed data channel is routed from IC 102 through BGA 112 to vias 1120, BGA 1114, flex circuit 1110, axial port 1106, twin axial cable 1104, axial port 1108, flex circuit 1112, BGA 1118, vias 1122, layer L2, and then to connector 104.

For FIG. 2 and FIGS. 7-11, it will be understood that the elements 202, 702, 802, 902, 1002, and 1102 may include routing for separate conductors to facilitate both send and receive for a high-speed data channel (e.g. Ethernet). In addition, elements 202, 702, 802, 902, 1002, and 1102 may include routing for multiple high-speed data channels, or a high-speed data channel with multiple lanes. Similarly, PCBs 204, 704, 812, 914, 1018, and 1118 may be configured to carry both a transmit and receive signal for a high-speed data channel so more than one set of vias and/or copper layer(s) may be routed in a PCB to facilitate transmit and receive signals for a high-speed data channel or to facilitate multiple high-speed data channels or a multi-lane data channel. FIG. 2 and FIGS. 7-11 show examples where one or more high-speed data channels is routed from IC 102 through a flex circuit and/or an axial cable to connector 104 rather than routing the high-speed data entirely (or the vast majority) through the PCB to connector 104. As the graphs in FIGS. 3-6 demonstrate, better signaling characteristics can be achieved using these embodiments rather than relying on low-cost PCB routing. Meanwhile, the various embodiments described herein support transmission quality levels that meet applicable standards, while being less expensive that using the optimized layer construction needed for high-cost PCB routing.

FIG. 12 depicts a cross-sectional view of a ceramic ball grid array (CBGA) 1200. In some embodiments, IC 102 and BGA 112 comprise a CBGA package having a structure similar to that shown in FIG. 12. In other embodiments, other types of BGAs may be used for the various BGAs illustrated in the Figures herein and described above. These include, but are not limited to plastic ball grid arrays and flip chip tape ball grid arrays. Generally, the “ball” structures of the various types of BGAs are similar to that shown in FIG. 12.

In Further detail, CBGA 1200 includes a die 1202 comprising the IC that is mounted to a multi-layer ceramic substrate 1204 by means of a flip-chip attach 1206. A plurality of solder balls 1208 are coupled in a grid pattern of eutectic solder 1210 on the underside of multi-layer ceramic substrate 1204. As further shown, a CPGA package may further include a cap 1212, thermal grease 1214, and underfill 1216.

FIG. 13 shows an example of the interconnections between BGA pads and vias. As discussed above, the BGA pads (depicted as BGA-PAD) are arranged in a pattern on an outer layer on a PCB (not shown). The vias 1300 are arranged is a similar pattern that is offset from the BGA pattern. In addition to having a 1:1 correspondence between BGA pads and vias, as shown in the left portion of FIG. 13, vias may be shared with multiple BGA pads, as shown in the right portion of FIG. 13, where SG means shared ground, SV means shared via, SP means shared power. In one embodiment, decoupling capacitors (DC) may be employed to reduce coupling between adjacent signals.

Further aspects of the subject matter described herein are set out in the following numbered clauses:

1. A circuit assembly comprising:

a multilayer printed circuit board (PCB);

an integrated circuit (IC) coupled to the printed circuit board;

a high-speed data connector coupled to the printed circuit board, the high-speed data connector being disposed at a distance greater than 3 inches from the integrated circuit (IC); and

a signal pathway coupled between the high-speed data connector and the integrated circuit, the signal pathway providing a high-speed data channel from the integrated circuit to the high-speed data connector having a bandwidth of at least 25 Gigabits per second (Gb/s), wherein a portion of the signal pathway includes a flexible (flex) circuit or axial cable having a length of at least 3 inches.

2. The circuit assembly of clause 1, wherein the high-speed data connector is disposed at least 10 inches from the IC.
3. The circuit assembly of clause 1 or 2, wherein the high-speed data channel has a bandwidth of at least 50 Gb/s.
4. The circuit assembly of clause 1 or 2, wherein the high-speed data channel employs a multi-lane link having a bandwidth of at least 100 Gigabits per second.
5. The circuit assembly of any of the preceding clauses, wherein the high-speed data connector comprises a small form-factor pluggable (SFP) connector.
6. The circuit assembly of any of the preceding clauses, wherein the high-speed data channels conforms to the transmitter signal specification defined by IEEE Std. 802.3 Clause 110 (25 GBASE-CR).
7. The circuit assembly of any of the preceding clauses, wherein the multilayer PCB comprises a first set of ball grid array (BGA) pads disposed on a first side of the PCB, a second set of BGA pads disposed on a second side of the PCB, a third set of BGA pads disposed on the second side of the PCB at least 3 inches away from the second set of BGA pads and a routing layer having a plurality of circuit paths formed on the first side of the multilayer PCB, wherein a portion of the first set of PGA pads are electronically coupled to the second set of BGA pads by a first plurality of vias passing through the multilayer PCB, and wherein the third set of BGA pads is coupled to first ends of circuit paths in the routing layer by a second plurality of vias passing through the multilayer PCB, and second ends of the circuit paths in the routing layer are coupled to a high-speed data connector mounted to the first side of the multilayer PCB;

wherein the IC is mounted to the multilayer PCB via a first BGA coupling the integrated circuit to the first side of the multilayer PCB via the first set of BGA pads,

the circuit assembly further comprising a BGA flex circuit having second and third BGAs disposed at opposing ends, the second BGA mounted to the second side of the multilayer PCB via the second set of BGA pads, the third BGA mounted to the second side of the multilayer PCB via the third set of BGA pads.

8. The circuit assembly of any of clauses 1-6, wherein the multilayer PCB comprises a first set of ball grid array (BGA) pads disposed on a first side of the PCB, a second set of BGA pads disposed on the first side of the PCB, and a third set of BGA pads disposed on the first side of the PCB at least 3 inches away from the second set of BGA pads and a first routing layer having a plurality of circuit paths formed on a second side of the multilayer PCB, the multilayer PCB further having first and second sets of vias passing through from the first side to the second side, wherein vias among the first and second sets of vias are electrically connected via circuit paths in the second routing layer, wherein a portion of the first set of PGA pads are electronically coupled to the first set of vias, and wherein the third set of BGA pads is coupled to circuit paths in the routing layer to a high-speed data connector mounted to the first side of the multilayer PCB; and

wherein the IC is mounted to the multilayer PCB via a first BGA coupling the integrated circuit to the first side of the multilayer PCB via the first set of BGA pads,

the circuit assembly further comprising a BGA flex circuit having second and third BGAs disposed at opposing ends, the second BGA mounted to the first side of the multilayer PCB via the second set of BGA pads, and the third BGA mounted to the first side of the multilayer PCB via the third set of BGA pads.

9. The circuit assembly of any of clauses 1-6, wherein the multilayer PCB comprises first and second sets of ball grid array (BGA) pads disposed on a first side of the multilayer PCB, and a routing layer having a plurality of circuit paths formed on the first side of the multilayer PCB connected at first ends to BGA pads in the second set of BGA pads;

wherein the high-speed data connector is mounted to the first side of the multilayer PCB and coupled to second ends of the plurality of circuit paths in the routing layer; and

wherein the IC is mounted to or integrated in a BGA/chip carrier including a first BGA mounted to a chip carrier/interposer board comprising a substrate that is interposed between the first BGA and a second BGA that is mounted to the multilayer PCB via the first set of BGA pads, wherein the chip carrier/interposer board includes a third set of BGA pads to which the first BGA is coupled and a fourth set of BGA pads,

the circuit assembly further comprising a BGA flex circuit having third and fourth BGAs disposed at opposing ends, the third BGA mounted to the chip carrier/interposer board via the fourth set of BGA pads, and the fourth BGA mounted to the first side of the multilayer PCB via the second set of BGA pads.

10. The circuit assembly of any of clauses 1-6, wherein the multilayer PCB comprises a first set of ball grid array (BGA) pads disposed on a first side of the PCB, a second set of BGA pads disposed on the first side of the PCB, and a third set of BGA pads disposed on the first side of the PCB at least 3 inches away from the second set of BGA pads and a first routing layer having a plurality of circuit paths formed on a second side of the multilayer PCB, the multilayer PCB further having first and second sets of vias passing through from the first side to the second side, wherein vias among the first and second sets of vias are electrically connected via circuit paths in the second routing layer, wherein a portion of the first set of PGA pads are electronically coupled to the first set of vias, and wherein the third set of BGA pads is coupled to circuit paths in the routing layer to a high-speed data connector mounted to the first side of the multilayer PCB; and

wherein the IC is mounted to the multilayer PCB via a first BGA coupling the integrated circuit to the first side of the multilayer PCB via the first set of BGA pads,

the circuit assembly further comprising a top flexible twin axial attachment including a twin axial cable coupled at a first end to a first axial port and coupled at a second end to a second axial port, the first axial port operatively coupled to a second BGA mounted to the first side of the multilayer PCB via the second set of BGA pads, and the second axial port operatively coupled to a third BGA mounted to the first side of the multilayer PCB via the third set of BGA pads.

11. The circuit assembly of clause 10, wherein the first axial port is operatively coupled to the second BGA by a first flex circuit, and wherein the second axial port is operatively coupled to the third BGA by a second flex circuit.
12. The circuit assembly of any of clauses 1-6, wherein the multilayer PCB comprises first and second sets of ball grid array (BGA) pads disposed on a first side of the multilayer PCB, and a routing layer having a plurality of circuit paths formed on the first side of the multilayer PCB connected at first ends to BGA pads in the second set of BGA pads;

wherein the high-speed data connector is mounted to the first side of the multilayer PCB and coupled to second ends of the plurality of circuit paths in the routing layer; and

wherein the IC is mounted to a first BGA mounted to the multilayer PCB via the first set of BGA pads, the first BGA including a substrate having a third set of BGA pads patterned on a top surface thereof,

the circuit assembly further comprising a top flexible twin axial attachment including a twin axial cable coupled at a first end to a first axial port and coupled at a second end to a second axial port, the first axial port operatively coupled to a second BGA mounted to the BGA substrate via the third set of BGA pads, and the second axial port operatively coupled to a third BGA mounted to the first side of the multilayer PCB via the second set of BGA pads.

13. The circuit assembly of clause 12, wherein the first axial port is operatively coupled to the second BGA by a first flex circuit, and wherein the second axial port is operatively coupled to the third BGA by a second flex circuit.
14. The circuit assembly of any of clauses 1-6, wherein the multilayer PCB comprises a first set of ball grid array (BGA) pads disposed on a first side of the PCB, a second set of BGA pads disposed on a second side of the PCB, a third set of BGA pads disposed on the second side of the PCB at least 3 inches away from the second set of BGA pads and a routing layer having a plurality of circuit paths formed on the first side of the multilayer PCB, wherein a portion of the first set of PGA pads are electronically coupled to the second set of BGA pads by a first plurality of vias passing through the multilayer PCB, and wherein the third set of BGA pads is coupled to first ends of circuit paths in the routing layer by a second plurality of vias passing through the multilayer PCB, and second ends of the circuit paths in the routing layer are coupled to a high-speed data connector mounted to the first side of the multilayer PCB;

wherein the IC is mounted to the multilayer PCB via a first BGA coupling the integrated circuit to the first side of the multilayer PCB via the first set of BGA pads,

the circuit assembly further comprising a bottom flexible twin axial attachment including a twin axial cable coupled at a first end to a first axial port and coupled at a second end to a second axial port, the first axial port operatively coupled to a second BGA mounted to the second side of the multilayer PCB via the second set of BGA pads, and the second axial port operatively coupled to a third BGA mounted to the second side of the multilayer PCB via the third set of BGA pads.

15. The circuit assembly of clause 15, wherein the first axial port is operatively coupled to the second BGA by a first flex circuit, and wherein the second axial port is operatively coupled to the third BGA by a second flex circuit.
16. A method of routing signals for a high-speed data channel between an integrated circuit (IC) mounted to a multilayer printed circuit board (PCB) and a high-speed data connector mounted to the multilayer PCB, the method comprising:

routing the signals from the IC to the high-speed data connector through a signal pathway supporting a bandwidth of at least 25 Gigabits per second (Gb/s), wherein a portion of the signal pathway includes a flexible (flex) circuit or axial cable having a length of at least 3 inches.

17. The method of clause 16, wherein the multilayer PCB comprises a first set of ball grid array (BGA) pads disposed on a first side of the PCB, a second set of BGA pads disposed on a second side of the PCB, a third set of BGA pads disposed on the second side of the PCB at least 3 inches away from the second set of BGA pads and a routing layer having a plurality of circuit paths formed on the first side of the multilayer PCB, wherein a portion of the first set of PGA pads are electronically coupled to the second set of BGA pads by a first plurality of vias passing through the multilayer PCB, and wherein the third set of BGA pads is coupled to first ends of circuit paths in the routing layer by a second plurality of vias passing through the multilayer PCB, and second ends of the circuit paths in the routing layer are coupled to a high-speed data connector mounted to the first side of the multilayer PCB;

wherein the IC is mounted to the multilayer PCB via a first BGA coupling the integrated circuit to the first side of the multilayer PCB via the first set of BGA pads,

the circuit assembly further comprising a BGA flex circuit having second and third BGAs disposed at opposing ends, the second BGA mounted to the second side of the multilayer PCB via the second set of BGA pads, the third BGA mounted to the second side of the multilayer PCB via the third set of BGA pads,

wherein the high-speed data channel is routed from the IC through the first BGA, through vias in the first set of vias, through the second BGA, through the flex circuit, through the third BGA, through vias in the second set of vias, and through the routing layer to high-speed data connector 104

18. The method of clause 16, wherein the multilayer PCB comprises a first set of ball grid array (BGA) pads disposed on a first side of the PCB, a second set of BGA pads disposed on the first side of the PCB, and a third set of BGA pads disposed on the first side of the PCB at least 3 inches away from the second set of BGA pads and a first routing layer having a plurality of circuit paths formed on a second side of the multilayer PCB, the multilayer PCB further having first and second sets of vias passing through from the first side to the second side, wherein vias among the first and second sets of vias are electrically connected via circuit paths in the second routing layer, wherein a portion of the first set of PGA pads are electronically coupled to the first set of vias, and wherein the third set of BGA pads is coupled to circuit paths in the routing layer to a high-speed data connector mounted to the first side of the multilayer PCB; and

wherein the IC is mounted to the multilayer PCB via a first BGA coupling the integrated circuit to the first side of the multilayer PCB via the first set of BGA pads,

the circuit assembly further comprising a BGA flex circuit having second and third BGAs disposed at opposing ends, the second BGA mounted to the first side of the multilayer PCB via the second set of BGA pads, and the third BGA mounted to the first side of the multilayer PCB via the third set of BGA pads,

wherein the high-speed data channel is routed from the IC through the first BGA, through vias in the first set of vias, through wiring in the second routing layer, through vias in the second set of vias, through the BGA flex circuit, through the first routing layer to the high-speed data connector.

19. The method of clause 16, wherein the multilayer PCB comprises first and second sets of ball grid array (BGA) pads disposed on a first side of the multilayer PCB, and a routing layer having a plurality of circuit paths formed on the first side of the multilayer PCB connected at first ends to BGA pads in the second set of BGA pads;

wherein the high-speed data connector is mounted to the first side of the multilayer PCB and coupled to second ends of the plurality of circuit paths in the routing layer; and

wherein the IC is mounted to or integrated in a BGA/chip carrier including a first BGA mounted to a chip carrier/interposer board comprising a substrate that is interposed between the first BGA and a second BGA that is mounted to the multilayer PCB via the first set of BGA pads, wherein the chip carrier/interposer board includes a third set of BGA pads to which the first BGA is coupled and a fourth set of BGA pads,

the circuit assembly further comprising a BGA flex circuit having third and fourth BGAs disposed at opposing ends, the third BGA mounted to the chip carrier/interposer board via the fourth set of BGA pads, and the fourth BGA mounted to the first side of the multilayer PCB via the second set of BGA pads,

wherein the high-speed data channel is routed from the IC through the first BGA, the chip carrier/interposer board, the second BGA, through the flex circuit, through the third BGA, through the routing layer to the high-speed data connector.

20. The method of clause 16, wherein the multilayer PCB comprises a first set of ball grid array (BGA) pads disposed on a first side of the PCB, a second set of BGA pads disposed on the first side of the PCB, and a third set of BGA pads disposed on the first side of the PCB at least 3 inches away from the second set of BGA pads and a first routing layer having a plurality of circuit paths formed on a second side of the multilayer PCB, the multilayer PCB further having first and second sets of vias passing through from the first side to the second side, wherein vias among the first and second sets of vias are electrically connected via circuit paths in the second routing layer, wherein a portion of the first set of PGA pads are electronically coupled to the first set of vias, and wherein the third set of BGA pads is coupled to circuit paths in the routing layer to a high-speed data connector mounted to the first side of the multilayer PCB; and

wherein the IC is mounted to the multilayer PCB via a first BGA coupling the integrated circuit to the first side of the multilayer PCB via the first set of BGA pads,

the circuit assembly further comprising a top flexible twin axial attachment including a twin axial cable coupled at a first end to a first axial port and coupled at a second end to a second axial port, the first axial port operatively coupled to a second BGA mounted to the first side of the multilayer PCB via the second set of BGA pads, and the second axial port operatively coupled to a third BGA mounted to the first side of the multilayer PCB via the third set of BGA pads,

wherein the high-speed data channel is routed from the IC through the first BGA, through vias in the first set of vias, through the second routing layer, through vias in the second set of vias, through the top flexible twin axial attachment to the routing layer to the high-speed data connector.

21. The method of clause 16, wherein the multilayer PCB comprises first and second sets of ball grid array (BGA) pads disposed on a first side of the multilayer PCB, and a routing layer having a plurality of circuit paths formed on the first side of the multilayer PCB connected at first ends to BGA pads in the second set of BGA pads;

wherein the high-speed data connector is mounted to the first side of the multilayer PCB and coupled to second ends of the plurality of circuit paths in the routing layer; and

wherein the IC is mounted to a first BGA mounted to the multilayer PCB via the first set of BGA pads, the first BGA including a substrate having a third set of BGA pads patterned on a top surface thereof,

the circuit assembly further comprising a top flexible twin axial attachment including a twin axial cable coupled at a first end to a first axial port and coupled at a second end to a second axial port, the first axial port operatively coupled to a second BGA mounted to the BGA substrate via the third set of BGA pads, and the second axial port operatively coupled to a third BGA mounted to the first side of the multilayer PCB via the second set of BGA pads,

wherein the high-speed data channel is routed from the IC through the first BGA, through the top flexible twin axial attachment, through the routing layer to the high-speed data connector.

22. The method of clause 16, wherein the multilayer PCB comprises a first set of ball grid array (BGA) pads disposed on a first side of the PCB, a second set of BGA pads disposed on a second side of the PCB, a third set of BGA pads disposed on the second side of the PCB at least 3 inches away from the second set of BGA pads and a routing layer having a plurality of circuit paths formed on the first side of the multilayer PCB, wherein a portion of the first set of PGA pads are electronically coupled to the second set of BGA pads by a first plurality of vias passing through the multilayer PCB, and wherein the third set of BGA pads is coupled to first ends of circuit paths in the routing layer by a second plurality of vias passing through the multilayer PCB, and second ends of the circuit paths in the routing layer are coupled to a high-speed data connector mounted to the first side of the multilayer PCB;

wherein the IC is mounted to the multilayer PCB via a first BGA coupling the integrated circuit to the first side of the multilayer PCB via the first set of BGA pads,

the circuit assembly further comprising a bottom flexible twin axial attachment including a twin axial cable coupled at a first end to a first axial port and coupled at a second end to a second axial port, the first axial port operatively coupled to a second BGA mounted to the second side of the multilayer PCB via the second set of BGA pads, and the second axial port operatively coupled to a third BGA mounted to the second side of the multilayer PCB via the third set of BGA pads,

wherein the high-speed data channel is routed from the IC through the first BGA, through vias in the first set of vias, through the bottom flexible twin axial attachment, through vias in the second set of vias, through the routing layer to the high-speed data connector.

23. The method of any of clauses 16-22, wherein the high-speed data connector is disposed at least 10 inches from the IC.
24. The method of any of clauses 16-23, wherein the high-speed data channel has a bandwidth of at least 50 Gb/s.
25. The method of any of clauses 16-23, wherein the high-speed data channels conforms to the transmitter signal specification defined by IEEE Std. 802.3 Clause 110 (25 GBASE-CR).
26. The circuit assembly of any of clauses 1-15, wherein the multilayer PCB comprises a server board.
27. The circuit assembly of any of clauses 1-15 and 26, wherein the IC comprises a processor with an integrated high-speed transceiver.
28. The circuit assembly of any of clauses 1-15, and 26, wherein the IC comprises a high-speed communication chip with an integrated high-speed transceiver.
29. The circuit assembly of any of clauses 1-15, 27 and 28, wherein the integrated high-speed transceiver is configured as one of an UltraPath Interconnect (UPI), Peripheral Component Interconnect Express (PCIe), Serial AT Attachment (SATA), Serial Attached SCSI (SAS), Universal Serial Bus (USB), Fiber Channel, and InfiniBand high-speed data interface.
30. The method of any of clauses 16-23, wherein the multilayer PCB comprises a server board.
31. The method of any of clauses 16-23 and 30, wherein the IC comprises a processor with an integrated high-speed transceiver.
32. The method of any of clauses 16-23, and 30, wherein the IC comprises a high-speed communication chip with an integrated high-speed transceiver.
33. The method of any of clauses 16-23, 31, and 32, wherein the integrated high-speed transceiver is configured as one of an UltraPath Interconnect (UPI), Peripheral Component Interconnect Express (PCIe), Serial AT Attachment (SATA), Serial Attached SCSI (SAS), Universal Serial Bus (USB), Fiber Channel, and InfiniBand high-speed data interface.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1.-25. (canceled)

26. A circuit assembly comprising:
a multilayer printed circuit board (PCB);
an integrated circuit (IC) coupled to the printed circuit board;
a high-speed data connector coupled to the printed circuit board, the high-speed data connector being disposed at a distance greater than 3 inches from the integrated circuit (IC); and
a signal pathway coupled between the high-speed data connector and the integrated circuit, the signal pathway providing a high-speed data channel from the integrated circuit to the high-speed data connector having a bandwidth of at least 25 Gigabits per second (Gb/s), wherein a portion of the signal pathway includes a flexible (flex) circuit or axial cable having a length of at least 3 inches.

27. The circuit assembly of claim 26, wherein the high-speed data connector is disposed at least 10 inches from the IC.

28. The circuit assembly of claim 26, wherein the high-speed data channel has a bandwidth of at least 50 Gb/s.

29. The circuit assembly of claim 26, wherein the high-speed data channel employs a multi-lane link having a bandwidth of at least 100 Gigabits per second.

30. The circuit assembly of claim 26, wherein the high-speed data connector comprises a small form-factor pluggable (SFP) connector.

31. The circuit assembly of claim 26, wherein the high-speed data channels conforms to the transmitter signal specification defined by IEEE Std. 802.3 Clause 110 (25 GBASE-CR).

32. The circuit assembly of claim 26, wherein the multilayer PCB comprises a first set of ball grid array (BGA) pads disposed on a first side of the PCB, a second set of BGA pads disposed on a second side of the PCB, a third set of BGA pads disposed on the second side of the PCB at least 3 inches away from the second set of BGA pads and a routing layer having a plurality of circuit paths formed on the first side of the multilayer PCB, wherein a portion of the first set of BGA pads are electronically coupled to the second set of BGA pads by a first plurality of vias passing through the multilayer PCB, and wherein the third set of BGA pads is coupled to first ends of circuit paths in the routing layer by a second plurality of vias passing through the multilayer PCB, and second ends of the circuit paths in the routing layer are coupled to a high-speed data connector mounted to the first side of the multilayer PCB;
wherein the IC is mounted to the multilayer PCB via a first BGA coupling the integrated circuit to the first side of the multilayer PCB via the first set of BGA pads,
the circuit assembly further comprising a BGA flex circuit having second and third BGAs disposed at opposing ends, the second BGA mounted to the second side of the multilayer PCB via the second set of BGA pads, the third BGA mounted to the second side of the multilayer PCB via the third set of BGA pads.

33. The circuit assembly of claim 26, wherein the multilayer PCB comprises a first set of ball grid array (BGA) pads disposed on a first side of the PCB, a second set of BGA pads disposed on the first side of the PCB, and a third set of BGA pads disposed on the first side of the PCB at least 3 inches away from the second set of BGA pads and a first routing layer having a plurality of circuit paths formed on a second side of the multilayer PCB, the multilayer PCB further having first and second sets of vias passing through from the first side to the second side, wherein vias among the first and second sets of vias are electrically connected via circuit paths in the second routing layer, wherein a portion of the first set of BGA pads are electronically coupled to the first set of vias, and wherein the third set of BGA pads is coupled to circuit paths in the routing layer to a high-speed data connector mounted to the first side of the multilayer PCB; and
wherein the IC is mounted to the multilayer PCB via a first BGA coupling the integrated circuit to the first side of the multilayer PCB via the first set of BGA pads,
the circuit assembly further comprising a BGA flex circuit having second and third BGAs disposed at opposing ends, the second BGA mounted to the first side of the multilayer PCB via the second set of BGA pads, and the third BGA mounted to the first side of the multilayer PCB via the third set of BGA pads.

34. The circuit assembly of claim 26, wherein the multilayer PCB comprises first and second sets of ball grid array (BGA) pads disposed on a first side of the multilayer PCB, and a routing layer having a plurality of circuit paths formed on the first side of the multilayer PCB connected at first ends to BGA pads in the second set of BGA pads;
wherein the high-speed data connector is mounted to the first side of the multilayer PCB and coupled to second ends of the plurality of circuit paths in the routing layer; and
wherein the IC is mounted to or integrated in a BGA/chip carrier including a first BGA mounted to a chip carrier/interposer board comprising a substrate that is interposed between the first BGA and a second BGA that is mounted to the multilayer PCB via the first set of BGA pads, wherein the chip carrier/interposer board includes a third set of BGA pads to which the first BGA is coupled and a fourth set of BGA pads,
the circuit assembly further comprising a BGA flex circuit having third and fourth BGAs disposed at opposing ends, the third BGA mounted to the chip carrier/interposer board via the fourth set of BGA pads, and the fourth BGA mounted to the first side of the multilayer PCB via the second set of BGA pads.

35. The circuit assembly of claim 26, wherein the multilayer PCB comprises a first set of ball grid array (BGA) pads disposed on a first side of the PCB, a second set of BGA pads disposed on the first side of the PCB, and a third set of BGA pads disposed on the first side of the PCB at least 3 inches away from the second set of BGA pads and a first routing layer having a plurality of circuit paths formed on a second side of the multilayer PCB, the multilayer PCB further having first and second sets of vias passing through from the first side to the second side, wherein vias among the first and second sets of vias are electrically connected via circuit paths in the second routing layer, wherein a portion of the first set of BGA pads are electronically coupled to the first set of vias, and wherein the third set of BGA pads is coupled to circuit paths in the routing layer to a high-speed data connector mounted to the first side of the multilayer PCB; and
wherein the IC is mounted to the multilayer PCB via a first BGA coupling the integrated circuit to the first side of the multilayer PCB via the first set of BGA pads,
the circuit assembly further comprising a top flexible twin axial attachment including a twin axial cable coupled at a first end to a first axial port and coupled at a second end to a second axial port, the first axial port operatively coupled to a second BGA mounted to the first side of the multilayer PCB via the second set of BGA pads, and the second axial port operatively coupled to a third BGA mounted to the first side of the multilayer PCB via the third set of BGA pads.

36. The circuit assembly of claim 35, wherein the first axial port is operatively coupled to the second BGA by a first flex circuit, and wherein the second axial port is operatively coupled to the third BGA by a second flex circuit.

37. The circuit assembly of claim 26, wherein the multilayer PCB comprises first and second sets of ball grid array (BGA) pads disposed on a first side of the multilayer PCB, and a routing layer having a plurality of circuit paths formed on the first side of the multilayer PCB connected at first ends to BGA pads in the second set of BGA pads;
wherein the high-speed data connector is mounted to the first side of the multilayer PCB and coupled to second ends of the plurality of circuit paths in the routing layer; and
wherein the IC is mounted to a first BGA mounted to the multilayer PCB via the first set of BGA pads, the first BGA including a substrate having a third set of BGA pads patterned on a top surface thereof,
the circuit assembly further comprising a top flexible twin axial attachment including a twin axial cable coupled at a first end to a first axial port and coupled at a second end to a second axial port, the first axial port operatively coupled to a second BGA mounted to the BGA substrate via the third set of BGA pads, and the second axial port operatively coupled to a third BGA mounted to the first side of the multilayer PCB via the second set of BGA pads.

38. The circuit assembly of claim 37, wherein the first axial port is operatively coupled to the second BGA by a first flex circuit, and wherein the second axial port is operatively coupled to the third BGA by a second flex circuit.

39. The circuit assembly of claim 26, wherein the multilayer PCB comprises a first set of ball grid array (BGA) pads disposed on a first side of the PCB, a second set of BGA pads disposed on a second side of the PCB, a third set of BGA pads disposed on the second side of the PCB at least 3 inches away from the second set of BGA pads and a routing layer having a plurality of circuit paths formed on the first side of the multilayer PCB, wherein a portion of the first set of BGA pads are electronically coupled to the second set of BGA pads by a first plurality of vias passing through the multilayer PCB, and wherein the third set of BGA pads is coupled to first ends of circuit paths in the routing layer by a second plurality of vias passing through the multilayer PCB, and second ends of the circuit paths in the routing layer are coupled to a high-speed data connector mounted to the first side of the multilayer PCB;
wherein the IC is mounted to the multilayer PCB via a first BGA coupling the integrated circuit to the first side of the multilayer PCB via the first set of BGA pads,
the circuit assembly further comprising a bottom flexible twin axial attachment including a twin axial cable coupled at a first end to a first axial port and coupled at a second end to a second axial port, the first axial port operatively coupled to a second BGA mounted to the second side of the multilayer PCB via the second set of BGA pads, and the second axial port operatively coupled to a third BGA mounted to the second side of the multilayer PCB via the third set of BGA pads.

40. The circuit assembly of claim 39, wherein the first axial port is operatively coupled to the second BGA by a first flex circuit, and wherein the second axial port is operatively coupled to the third BGA by a second flex circuit.

41. A method of routing signals for a high-speed data channel between an integrated circuit (IC) mounted to a multilayer printed circuit board (PCB) and a high-speed data connector mounted to the multilayer PCB, the method comprising:
routing the signals from the IC to the high-speed data connector through a signal pathway supporting a bandwidth of at least 25 Gigabits per second (Gb/s), wherein a portion of the signal pathway includes a flexible (flex) circuit or axial cable having a length of at least 3 inches.

42. The method of claim 41, wherein the multilayer PCB comprises a first set of ball grid array (BGA) pads disposed on a first side of the PCB, a second set of BGA pads disposed on a second side of the PCB, a third set of BGA pads disposed on the second side of the PCB at least 3 inches away from the second set of BGA pads and a routing layer having a plurality of circuit paths formed on the first side of the multilayer PCB, wherein a portion of the first set of BGA pads are electronically coupled to the second set of BGA pads by a first plurality of vias passing through the multilayer PCB, and wherein the third set of BGA pads is coupled to first ends of circuit paths in the routing layer by a second plurality of vias passing through the multilayer PCB, and second ends of the circuit paths in the routing layer are coupled to a high-speed data connector mounted to the first side of the multilayer PCB;
wherein the IC is mounted to the multilayer PCB via a first BGA coupling the integrated circuit to the first side of the multilayer PCB via the first set of BGA pads,
the circuit assembly further comprising a BGA flex circuit having second and third BGAs disposed at opposing ends, the second BGA mounted to the second side of the multilayer PCB via the second set of BGA pads, the third BGA mounted to the second side of the multilayer PCB via the third set of BGA pads,
wherein the high-speed data channel is routed from the IC through the first BGA, through vias in the first set of vias, through the second BGA, through the flex circuit, through the third BGA, through vias in the second set of vias, and through the routing layer to high-speed data connector 104

43. The method of claim 41, wherein the multilayer PCB comprises a first set of ball grid array (BGA) pads disposed on a first side of the PCB, a second set of BGA pads disposed on the first side of the PCB, and a third set of BGA pads disposed on the first side of the PCB at least 3 inches away from the second set of BGA pads and a first routing layer having a plurality of circuit paths formed on a second side of the multilayer PCB, the multilayer PCB further having first and second sets of vias passing through from the first side to the second side, wherein vias among the first and second sets of vias are electrically connected via circuit paths in the second routing layer, wherein a portion of the first set of BGA pads are electronically coupled to the first set of vias, and wherein the third set of BGA pads is coupled to circuit paths in the routing layer to a high-speed data connector mounted to the first side of the multilayer PCB; and
wherein the IC is mounted to the multilayer PCB via a first BGA coupling the integrated circuit to the first side of the multilayer PCB via the first set of BGA pads,
the circuit assembly further comprising a BGA flex circuit having second and third BGAs disposed at opposing ends, the second BGA mounted to the first side of the multilayer PCB via the second set of BGA pads, and the third BGA mounted to the first side of the multilayer PCB via the third set of BGA pads,
wherein the high-speed data channel is routed from the IC through the first BGA, through vias in the first set of vias, through wiring in the second routing layer, through vias in the second set of vias, through the BGA flex circuit, through the first routing layer to the high-speed data connector.

44. The method of claim 41, wherein the multilayer PCB comprises first and second sets of ball grid array (BGA) pads disposed on a first side of the multilayer PCB, and a routing layer having a plurality of circuit paths formed on the first side of the multilayer PCB connected at first ends to BGA pads in the second set of BGA pads;
wherein the high-speed data connector is mounted to the first side of the multilayer PCB and coupled to second ends of the plurality of circuit paths in the routing layer; and
wherein the IC is mounted to or integrated in a BGA/chip carrier including a first BGA mounted to a chip carrier/interposer board comprising a substrate that is interposed between the first BGA and a second BGA that is mounted to the multilayer PCB via the first set of BGA pads, wherein the chip carrier/interposer board includes a third set of BGA pads to which the first BGA is coupled and a fourth set of BGA pads,
the circuit assembly further comprising a BGA flex circuit having third and fourth BGAs disposed at opposing ends, the third BGA mounted to the chip carrier/interposer board via the fourth set of BGA pads, and the fourth BGA mounted to the first side of the multilayer PCB via the second set of BGA pads,
wherein the high-speed data channel is routed from the IC through the first BGA, the chip carrier/interposer board, the second BGA, through the flex circuit, through the third BGA, through the routing layer to the high-speed data connector.

45. The method of claim 41, wherein the multilayer PCB comprises a first set of ball grid array (BGA) pads disposed on a first side of the PCB, a second set of BGA pads disposed on the first side of the PCB, and a third set of BGA pads disposed on the first side of the PCB at least 3 inches away from the second set of BGA pads and a first routing layer having a plurality of circuit paths formed on a second side of the multilayer PCB, the multilayer PCB further having first and second sets of vias passing through from the first side to the second side, wherein vias among the first and second sets of vias are electrically connected via circuit paths in the second routing layer, wherein a portion of the first set of BGA pads are electronically coupled to the first set of vias, and wherein the third set of BGA pads is coupled to circuit paths in the routing layer to a high-speed data connector mounted to the first side of the multilayer PCB; and
wherein the IC is mounted to the multilayer PCB via a first BGA coupling the integrated circuit to the first side of the multilayer PCB via the first set of BGA pads,
the circuit assembly further comprising a top flexible twin axial attachment including a twin axial cable coupled at a first end to a first axial port and coupled at a second end to a second axial port, the first axial port operatively coupled to a second BGA mounted to the first side of the multilayer PCB via the second set of BGA pads, and the second axial port operatively coupled to a third BGA mounted to the first side of the multilayer PCB via the third set of BGA pads,
wherein the high-speed data channel is routed from the IC through the first BGA, through vias in the first set of vias, through the second routing layer, through vias in the second set of vias, through the top flexible twin axial attachment to the routing layer to the high-speed data connector.

46. The method of claim 41, wherein the multilayer PCB comprises first and second sets of ball grid array (BGA) pads disposed on a first side of the multilayer PCB, and a routing layer having a plurality of circuit paths formed on the first side of the multilayer PCB connected at first ends to BGA pads in the second set of BGA pads;
wherein the high-speed data connector is mounted to the first side of the multilayer PCB and coupled to second ends of the plurality of circuit paths in the routing layer; and
wherein the IC is mounted to a first BGA mounted to the multilayer PCB via the first set of BGA pads, the first BGA including a substrate having a third set of BGA pads patterned on a top surface thereof,
the circuit assembly further comprising a top flexible twin axial attachment including a twin axial cable coupled at a first end to a first axial port and coupled at a second end to a second axial port, the first axial port operatively coupled to a second BGA mounted to the BGA substrate via the third set of BGA pads, and the second axial port operatively coupled to a third BGA mounted to the first side of the multilayer PCB via the second set of BGA pads,
wherein the high-speed data channel is routed from the IC through the first BGA, through the top flexible twin axial attachment, through the routing layer to the high-speed data connector.

47. The method of claim 41, wherein the multilayer PCB comprises a first set of ball grid array (BGA) pads disposed on a first side of the PCB, a second set of BGA pads disposed on a second side of the PCB, a third set of BGA pads disposed on the second side of the PCB at least 3 inches away from the second set of BGA pads and a routing layer having a plurality of circuit paths formed on the first side of the multilayer PCB, wherein a portion of the first set of BGA pads are electronically coupled to the second set of BGA pads by a first plurality of vias passing through the multilayer PCB, and wherein the third set of BGA pads is coupled to first ends of circuit paths in the routing layer by a second plurality of vias passing through the multilayer PCB, and second ends of the circuit paths in the routing layer are coupled to a high-speed data connector mounted to the first side of the multilayer PCB;
wherein the IC is mounted to the multilayer PCB via a first BGA coupling the integrated circuit to the first side of the multilayer PCB via the first set of BGA pads,
the circuit assembly further comprising a bottom flexible twin axial attachment including a twin axial cable coupled at a first end to a first axial port and coupled at a second end to a second axial port, the first axial port operatively coupled to a second BGA mounted to the second side of the multilayer PCB via the second set of BGA pads, and the second axial port operatively coupled to a third BGA mounted to the second side of the multilayer PCB via the third set of BGA pads,
wherein the high-speed data channel is routed from the IC through the first BGA, through vias in the first set of vias, through the bottom flexible twin axial attachment, through vias in the second set of vias, through the routing layer to the high-speed data connector.

48. The method of claim 41, wherein the high-speed data connector is disposed at least 10 inches from the IC.

49. The method of claim 41, wherein the high-speed data channel has a bandwidth of at least 50 Gb/s.

50. The method of claim 41, wherein the high-speed data channels conforms to the transmitter signal specification defined by IEEE Std. 802.3 Clause 110 (25 GBASE-CR).
